(19) United States
(12) Patent Application Publication
(10) Pub. No.: US 2010/0332177 A1
(43) Pub. Date: Dec. 30, 2010

(54) TEST ACCESS CONTROL APPARATUS AND METHOD THEREOF

(75) Inventors: CHENG WEN WU, HSINCHU (TW); CHIH YEN LO, HSINCHU (TW); YU TSAO HSING, TAIPEI COUNTY (TW)

Correspondence Address: WPAT, PC;INTELLECTUAL PROPERTY ATTORNEYS, 2030 MAIN STREET, SUITE 1300, IRVINE, CA, 92614, US

(73) Assignee: NATIONAL TSING HUA UNIVERSITY, HSINCHU (TW)

(21) Appl. No.: 12/495,036

(22) Filed: Jun. 30, 2009

(51) Int. Cl. G01R 31/00; G06F 19/00

(52) U.S. Cl. 702/117

(57) ABSTRACT

A test access control apparatus includes test access mechanism (TAM) buses and an extended IEEE 1149.1 Test Access Port (TAP) Controller. The TAM buses support memory built-in-self-test (BIST) circuit for the memory known-good-die (KGD) test, scan chains for the logic KGD test; and through-silicon-via (TSV) chains that are configured to conduct the TSV test that verifies any defect in vertical interconnects between any two chip layers of the stacked chip device. The TAP Controller is coupled to the TAM buses and is configured to control the memory KGD test, the logic KGD test and the TSV test between two chip layers. A cost-effective connection or configuration of test access control apparatus in 3D-IC is also present. In accordance with an embodiment of the present invention, a test access control method includes a yield-concerned test methodology for 3D-IC, and an integrated flow of test access control apparatus supporting heterogeneous test protocols of SOC

### BACKGROUND OF THE INVENTION

(A) Field of the Invention

The present invention is related to a test access control apparatus and method for a stacked chip device.

(B) Description of the Related Art

Three-dimensional (3D) integration or wafer-to-wafer or chip-to-chip bonding technology has been considered the most promising solution to extend the life of Moore's law in semiconductor manufacturing technology. However, the stacked dies employed in such technologies will face the severe problem of exponential decay in quality if the currently employed post-bond testing technique is not changed.

Through-silicon via (TSV) is the latest in a progression of technologies for stacking silicon devices in 3D arrangements. Placing and wiring devices in 3D promises higher clock rates, lower power dissipation, and higher integration density. 3D TSV technology will be adopted in many applications because it solves issues related to electrical performance, memory latency, power, and noise on and off the chip. For some applications, a high-bandwidth memory interface to the logic has been the main driver for the development of TSV technology. However, the available TSV for 3D-IC testing is highly related to its overall test cost.

Expectations for the technology are running high, but the integration of the TSV test with the current memory test and logic test forms a barrier to using the technology. Therefore, there is a need for an architecture and a method that can efficiently perform the above-mentioned integrated testing.

### SUMMARY OF THE INVENTION

The present invention provides a test access control apparatus and method for stacked chip devices that can perform System On Chip (SOC) test and TSV verification in pre-bond and post-bond testing stages. Therefore, the yield of the stacked chip devices can be better assured.

In accordance with an embodiment of the present invention, a test access control apparatus for testing a stacked chip device includes a test access mechanism (TAM) buses and an extended IEEE 1149.1 Test Access Port (TAP) Controller coupled to the TAM buses. The TAM buses can support related controls of a memory built-in-self-test (BIST) circuit for memory known-good-die (KGD) test, scan chains for logic known-good-die test, and TSV chains for conducting a TSV test that verifies any defect appeared in vertical interconnects of the stacked chip device. The TAP Controller is configured to control the process for various KGD tests before chips can be stacked and also includes vertical interconnect verification after chips are stacked. Several explanatory connections and configurations of test access control apparatus in 3D-IC are also presented.

In accordance with an embodiment of the present invention, a test access control method includes steps of performing known-good-die (KGD) test before chip stacking; bonding chips layer by layer with TSVs or vertical interconnects; and performing optional KGD test after chips are stacked.

### BRIEF DESCRIPTION OF THE DRAWINGS

FIG. 1 shows a test access control apparatus in accordance with an embodiment of the present invention;

FIGS. 2 and 3 show a test access control method in accordance with an embodiment of the present invention; and

FIGS. 4A, 4B and 4C show configurations and settings of the test access control apparatus for a KGD test or TSV verification before and after the chip layers are stacked in accordance with embodiments of the present invention.

### DETAILED DESCRIPTION OF THE INVENTION

The present invention will be explained with the appended drawings to clearly disclose the technical characteristics of the present invention.

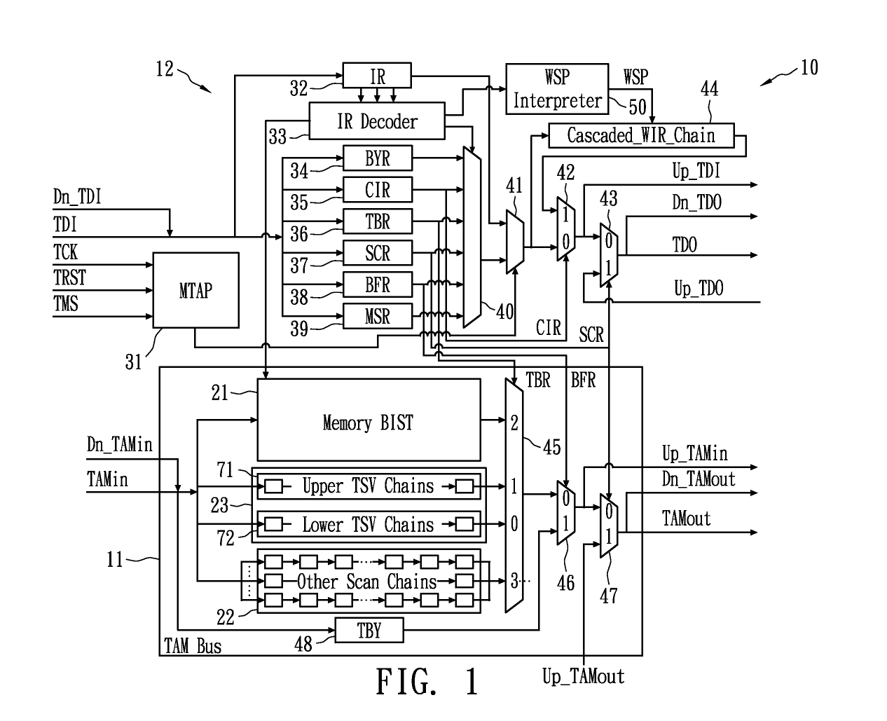

FIG. 1 shows a test access control apparatus for testing a stacked chip device (3D-IC) in accordance with an embodiment of the present invention. The stacked chip device comprises at least a first chip layer (lower chip layer) and a second chip layer (upper chip layer). Each layer of 3D-IC will implement a test access control apparatus. A test access control apparatus 10 includes test access mechanism (TAM) buses 11 and an extended IEEE 1149.1 Test Access Port (TAP) Controller 12. The TAM buses 11 support related test control and/or test instructions to memory built-in-self-test (BIST) circuit 21 for the memory known-good-die (KGD) test, scan chains 22 for the logic KGD test; and through-silicon-via (TSV) chains 23 that are configured to conduct the TSV test that verifies any defect in vertical interconnects between any two chip layers of the stacked chip device. The TAP Controller 12 is coupled to the TAM buses 11 and is configured to control the memory KGD test, the logic KGD test and the TSV test between two chip layers before and after the chips are stacked.

The TAP Controller 12 include a MTAP 31 which is a finite state machine, an Instruction Register (IR) 32, an IR decoder 33, a bypass register (BYR) 34, a Core Identity Register (CIR) 35, a TAM Bus Register (TBR) 36, a single-cascade register (SCR) 37, a bypass flag register (BFR) 38, a MBIST start register (MSR) 39. The MTAP 31 receives a TCK signal, a TRST signal, and a TMS signal. TCK represents the test clock and TRST is the test reset signal. TMS controls the generation of control signals of various test protocols. The inputs of the BYR 34, the CIR 35, the TBR 36, the SCR 37, the BFR 38, and the MSR 39 receive Dn_TDI or TDI signal, and the outputs thereof are connected to a multiplexer 40. Data for test configuration are transmitted through TDI or Dn_TDI. The IR 32 receives TDI and stores the data for test configuration. The input of IR decoder 33 receives the data stored in IR 32. The output of the IR decoder 33 is connected to a WSP (Wrapper Serial Port) interpreter 50 and the multiplexer 40. The output of the WSP interpreter 50 is connected to a cascade_WIR_chain 44. The output of the WSP interpreter 50 is coupled to a cascade_WIR_Chain 44. Multiplexers 41, 42 and 43 output Up_TDI, Dn_TDO and TDO signals. The TSV chains 23 include upper TSV chains 71 and lower TSV chains 72 for testing vertical interconnects in the upper chip layer and the lower chip layer.

The memory BIST circuit 21, the TSV chains 23 and the scan chains 22 in parallel receive a Dn_TAMin or TAMin signal for test patterns application, and their outputs are connected to a multiplexer 45 which further receives a TBR signal. The Dn_TAMin signal represents the inputs for test pattern from a lower chip layer of a stacked chip device and is transmitted to a bypass unit named TAM Bypass unit (TBY) 48 that is configured to control whether the KGD test in current layer is bypassed. A multiplexer 46 receives the output signals from the TBY 48 and the multiplexer 45 and BFR signal, and the output of the multiplexer 46 is connected to Up_TAMin which transmits the test pattern for an upper chip layer of the stacked chip device. Moreover, a multiplexer 47 is connected to the output of the multiplexer 46 and the SCR signal, and outputs of the multiplexer 47 are connected to Dn_TAMout or TAMout.

In brief, this invention proposes a test access control apparatus for 3D-IC. The test access port controller may use an extended JTAG/IEEE 1149.1, and for applying logic testing a test access control apparatus features IEEE 1500 Wrapper Control, hierarchical test control, at-speed test (for transition faults), functional and scan test, heterogeneous test protocols, etc. In order to save the control signal pins/TSVs, the test access port controller is further extended to support memory BIST (MBIST) in the stacked chips by adding MSR 39 in the test access port controller 12 and defining a special TAM switching. The 3D interconnect verification can be easily applied through the operations of SCR 37 and BFR 38.

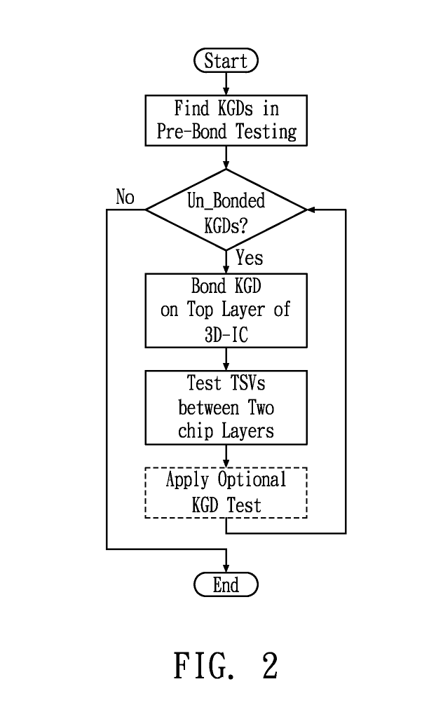

FIG. 2 shows a practical system-on-chip (SOC) test strategy which can be applied to reconfigured wafer-on-wafer or chip-on-chip 3D integration technology. To mitigate the yield issues of 3D-IC manufacturing, a known-good-die (KGD) test is performed for a chip layer before die stacking. If the chip layer has un-bonded good dies, the chip layer is bonded so as to form a 3D-IC. After bonding, a TSV test between the two chip layers is performed, and the 3D-IC may be subjected to an optional KGD test such as a KGD test in the bottom layer of the 3D-IC. Accordingly, a number of the chip layers can be bonded repeatedly to form a 3D-IC.

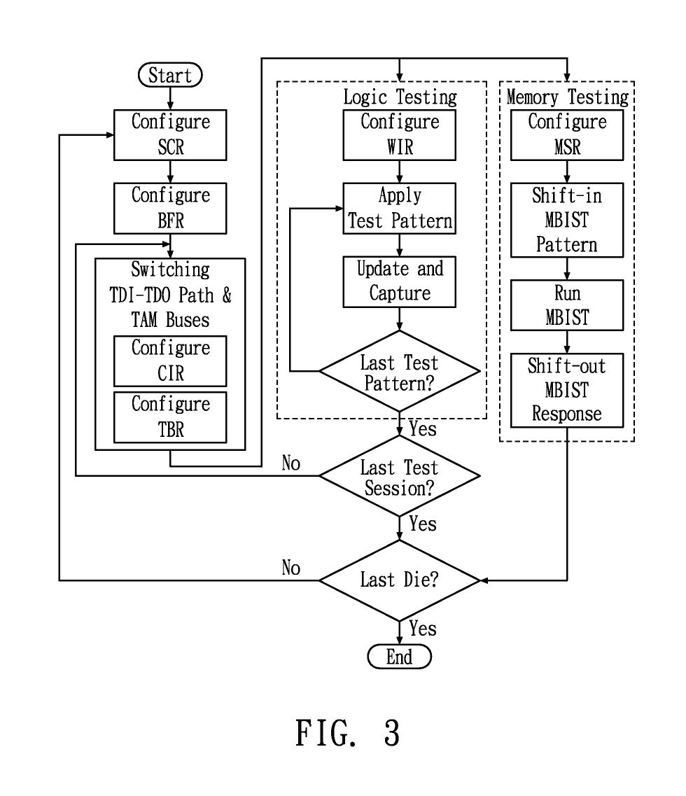

The details of locating a KGD are shown in FIG. 3. The SCR and BFR are configured, and then the path from TDI to TDO and the TAM bus 11 are switched based on IR 32 and TBR.36. At the same time, the CIR and TBR are configured. If the paths are switched for memory testing, MSR is configured, and an MBIST pattern is shifted-in. Then, the MBIST is executed, and the MBIST response is shifted-out. If the paths are switched for logic testing, WIR of the targeted core is configured. Test patterns are applied, updated and captured until the last test pattern is applied. By our special arrangement, the flows for logic and memory testing are highly integrated in our test access control apparatus. The logic testing and the memory testing are repeated until the last die is subjected to the testing.

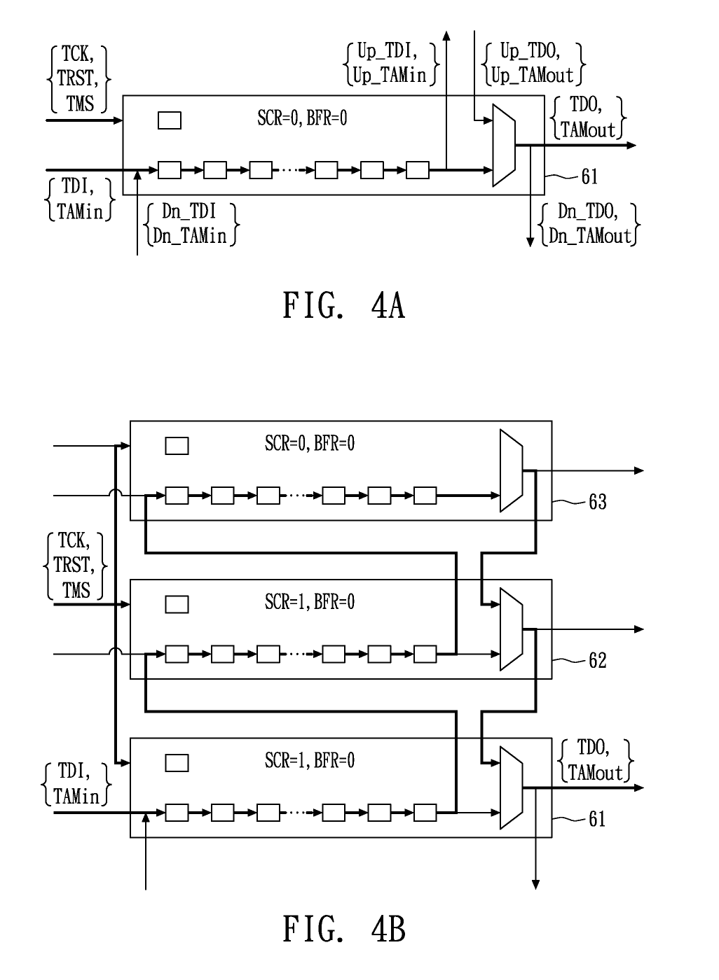

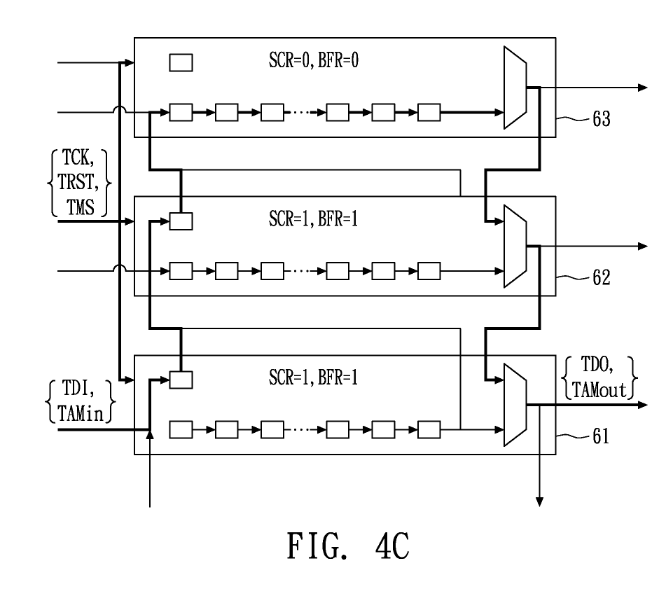

FIG. 4A shows a detailed setting of pre-stack KGD test, in which SCR is set to 0 (a first logic level) and BFR is set to 0. SCR=0 and BFR=0 denotes that the test for this chip layer 61 is not bypassed.

We also propose the way to operate test access control apparatuses in different layers of 3D-IC in FIGS. 4B and 4C. We extend the interface of IEEE 1149.1 TAP Controller to control KGD tests and TSV tests in 3D-IC. In these figures to illustrate cost-effective 3D-IC test, TCK, TRST and TMS signals are broadcasted to all test access control apparatus, while the paths for test configuration and data application are connected in a serial way. The Dn_TDI, Dn_TDO, Dn_TAMin, and Dn_TAMout are ports to communicate with the lower layer. The Up_TDI, Up_TDO, Up_TAMin, and Up_TAMout are ports to communicate with the upper layer.

FIG. 4B shows a setting of a parallel TSV test, in which in chip layers 61 and 62 SCR=1 (a second logic level) and BFR=0, and in the chip layer 63 SCR=0 and BFR=0. Consequently, the chip layers 61, 62 and 63 are subjected to parallel TSV testing. Because SCR=0 in the chip layer 63, the test will not be performed on an upper chip layer.

FIG. 4C shows the setting for an optional KGD test on the top layer of the stacked chips, in which in chip layers 61 and 62 SCR=1 and BFR=1, and in chip layer 63 SCR=0 and BFR=0. Accordingly, the KGD test for chip layers 61 and 62 is bypassed, and only the chip layer 63, i.e., the top chip layer of this embodiment, is subjected to the KGD test. The above embodiments are exemplified only, and the first and second logic levels may be swapped as desired.

Based on such proposed test scheme and TACS-3D, the yield issues of the 3D-IC can be easily mitigated by flexibly executing an SOC test before and after dies are mounted. In addition, shorter overall test time is expected due to uniform test interface and reduced test-control requirements.

By special arrangement of SOC test integration, logic or memory testing with simple test configuration and small area overhead can be flexibly executed. After KGDs are obtained, the stacked chip device can be formed by layer-by-layer mounting. Every time a new KGD is mounted on the original stacked chip, the TSV test may be performed for 3D interconnect verification between the two chip layers. If necessary, the proposed test scheme also supports an extra KGD test in every layer of the stack with neither extra test circuits nor modified test application. Therefore, the yield of the stacked chips can be better assured.

The above-described embodiments of the present invention are intended to be illustrative only. Numerous alternative embodiments may be devised by those skilled in the art without departing from the scope of the following claims.

What is claimed is:

1. A test access control apparatus for testing a stacked chip device, comprising:
test access mechanism (TAM) buses, supporting:
a memory built-in-self-test (BIST) circuit for a memory known-good-die test;
scan chains for a logic known-good-die (KGD) test; and
through-silicon-via (TSV) chains configured to conduct a TSV test that verifies any defect between at least two chip layers of the stacked chip device; and
a Test Access Port (TAP) controller coupled to the test access mechanism buses and configured to control the memory KGD test, the logic KGD test and the TSV test in the at least two chip layers;
wherein the test access control apparatus is implemented in every layer of the stacked chip device.

2. The test access control apparatus of claim 1, wherein the at least two chip layers comprise a first chip layer and a second chip layer, the first chip layer being disposed below the second chip layer.

3. The test access control apparatus of claim 2, wherein the TSV chains comprise upper TSV chains and lower TSV chains for testing the second chip layer and the first chip layer, respectively.

4. The test access control apparatus of claim 2, wherein the TAP controller comprises a single-cascade register (SCR) that is configured to determine whether the first chip layer and the second chip layer are subjected to the TSV test in parallel.

5. The test access control apparatus of claim 4, wherein the TAP controller further comprises a bypass flag register (BFR) that is configured to determine whether the KGD test in the first chip layer or the second chip layer is bypassed.

6. The test access control apparatus of claim 5, wherein SCR is set to a first logic level and BFR is set to the first logic level for the second chip layer when the second chip layer is subjected to the KGD test.

7. The test access control apparatus of claim 6, wherein the KGD test is performed in the second chip layer before the second chip layer and the first chip layer are stacked.

8. The test access control apparatus of claim 5, wherein BFR is set to a first logic level for the first chip layer and the second chip layer, and SCR is set to a second logic level for the first chip layer and the second chip layer when the TSV test is performed in the first chip layer and the second chip layer in parallel.

9. The test access control apparatus of claim 5, wherein the second chip layer is a top chip layer, the SCR is set to a first logic level and the BFR is set to the first logic level for the second chip layer, the SCR is set to a second logic level and BFR is set to the second logic level for the first chip layer when performing the KGD test in the top chip layer.

10. The test access control apparatus of claim 5, wherein the TAP controller further comprises a memory BIST start register.

11. A test access control method, comprising the steps of:
performing a known-good-die (KGD) test for a plurality of chip layers comprising at least a first chip layer and a second chip layer;
bonding the second chip layer to the first chip layer to form a stacked chip device;
performing a through-silicon-via (TSV) test between the first and second chip layers; and
performing optional KGD test.

12. The test access control method of claim 11, wherein the plurality of chip layers further comprise a third chip layer, and a step of bonding the third chip layer is performed after the step of performing optional KGD test.

13. The test access control method of claim 11, further comprising a step of providing a single-cascade register (SCR) configured to determine whether the first chip layer and the second chip layer are subjected to the TSV test in parallel and a bypass flag register (BFR) configured to determine whether the KGD test in the first chip layer or the second chip layer is bypassed.

14. The test access control method of claim 13, wherein the SCR is set to a first logic level and BFR is set to the first logic level for the second chip layer when the second chip layer is subjected to the KGD test.

15. The test access control method of claim 14, wherein the KGD test is performed in the second chip layer before the second chip layer and the first chip layer are stacked.

16. The test access control method of claim 13, wherein BFR is set to a first logic level for the first chip layer and the second chip layer, and SCR is set to a second logic level for the first chip layer and the second chip layer when the TSV test is performed in the first chip layer and the second chip layer in parallel.

17. The test access control method of claim 13, wherein the first chip layer is a bottom chip layer, the SCR is set to a second logic level and the BFR is set to the second logic level for the first chip layer, the SCR is set to a first logic level and BFR is set to the first logic level for the second chip layer when performing a KGD test in the top chip layer.

18. The test access control method of claim 11, wherein the KGD test includes logic testing and memory testing.
